(19) United States
(12) Patent Application Publication
(10) Pub. No.: US 2022/0319875 A1
(43) Pub. Date: Oct. 6, 2022

(54) SUBSTRATE DRYING APPARATUS AND SUBSTRATE PROCESSING APPARATUS

(71) Applicant: SHIBAURA MECHATRONICS CORPORATION, Yokohama-shi (JP)

(72) Inventor: Yoko TARUNO, Yokohama-shi (JP)

(73) Assignee: SHIBAURA MECHATRONICS CORPORATION, Yokohama-shi (JP)

(21) Appl. No.: 17/656,059

(22) Filed: Mar. 23, 2022

(30) Foreign Application Priority Data
Mar. 31, 2021 (JP) 2021-059075

(51) Int. Cl. H01L 21/67; B08B 3/08; B08B 13/00

(52) U.S. Cl. CPC H01L 21/67034; B08B 3/08; B08B 13/00

(57) ABSTRACT

A substrate drying apparatus and a substrate processing apparatus that can reduce the blockade of patterns are provided. The substrate drying apparatus according to one embodiment includes: the drier (substrate drying apparatus) of the present disclosure, includes the heater which heats the substrate, the drying room into which the substrate wherein the liquid film of the processing liquid is formed on the surface to be processed is carried in, the support which receives the substrate carried into the drying room at the standby position distant from the heater, and the driving mechanism which moves the substrate close to the heater and ejects the liquid at which the gas layer is produced between the substrate heated by the heater and the liquid film by centrifugal force due to the rotation of the substrate.

### CROSS-REFERENCE TO RELATED APPLICATION

This application is based upon and claims the benefit of priority from Japan Patent Application No. 2021-059075, filed on Mar. 31, 2021, the entire contents of which are incorporated herein by reference.

### FIELD OF INVENTION

The present disclosure relates to a substrate drying apparatus and a substrate processing apparatus.

### BACKGROUND

In manufacturing processes to manufacture semiconductors and liquid crystal panels, etc., a substrate processing apparatus that supplies processing liquid on a surface of a substrate to be processed, such as wafers and liquid crystal substrates, processes the surface, and after the processing, washes and dries the surface is used. In the drying process of the substrate processing apparatus, patterns around memory cells and gates, etc., may collapse and be blocked due to intervals between the patterns, structures of the patterns, and surface tension of the processing liquid. This trend is advancing along with recent die shrinking of semiconductors to achieve higher integration and larger capacity.

To suppress the above-described collapsing of the patterns, a substrate drying method using IPA (2-propanol: isopropyl alcohol) which has the surface tension lower than ultrapure water is suggested. In this substrate drying method, DIW (ultrapure water) on the surface of the substrate is replaced by the mixture solution of IPA and DIW to dry the substrate (refer Japanese Laid-Open application 2008-034779).

### SUMMARY OF INVENTION

### Problems to be Solved by Invention

However, die shrinking of semiconductors is further advancing, and fine patterns of the wafer may collapse due to surface tension of liquid, etc., even when the substrate was dried by using organic solution with high volatility like IPA.

For example, if drying speed of the surface of the substrate becomes ununiformly while drying the liquid and the liquid remains on some portions between the patterns, the patterns collapse due to the surface tension of the liquid on said portions. In detail, the patterns where the liquid remained collapse due to elastic transformation caused by the surface tension of the liquid, and little residues dissolved in the liquid aggregates. Then, when the liquid completely vaporize, the collapse patterns adhere with each other.

Objective of the present disclosure is to provide a substrate drying apparatus and a substrate processing apparatus that can reduce blockades of the patterns.

### Means to Solve the Problem

A substrate drying apparatus of the present disclosure includes:

a heater that heats a substrate;

a drying room inside which the heater is housed and into which the substrate is carried, in which liquid film of processing liquid is formed on a surface of the substrate;

a support which receives the substrate that has been carried into the drying room at a standby position distant from the heater; and

a driving mechanism which rotates the substrates supported by the support while moving the substrate to a drying position near the heater to eject the liquid film by centrifugal force caused by rotation of the substrate, in which a gas layer is produced between the liquid film and the substrate heated by the heater.

A substrate processing apparatus of the present disclosure includes:

a processing device which applies processing liquid to a substrate and processes the substrate, while rotating the substrate;

a washing device which applies washing liquid to the processed substrate and washed the processed substrate, while rotating the processed substrate;

a substrate drying apparatus; and

a transporter which carries out the substrate washed by the washing device, in which liquid film of the washing liquid is formed on the surface of the substrate, and carries the substrate into the substrate drying apparatus.

### Effect of Invention

The present disclosure can provide the substrate drying apparatus and the substrate processing apparatus that can reduce blockades of the patterns.

### BRIEF DESCRIPTION OF DRAWINGS

FIG. 1 is a simple configuration diagram illustrating a substrate processing apparatus of an embodiment.

FIG. 2 is a configuration diagram illustrating a washing device and a drier of the substrate processing apparatus of FIG. 1.

FIG. 3 is an inner configuration diagram illustrating a drier at the time of carrying in a substrate (A) and at the time of measuring film thickness (B).

FIG. 4 is an inner configuration diagram illustrating a drier at the time of supplying washing liquid (A) and at the time of substrate standing by (B).

FIG. 5 is an inner configuration diagram illustrating a drier at the time of drying a substrate (C) and at the time of descending a substrate (B).

FIG. 6 is a flowchart illustrating procedures for drying a substrate of an embodiment.

FIG. 7 is an explanation diagram illustrating a flow of drying using Leidenfrost phenomenon

FIG. 8 is a configuration diagram illustrating a modified example in which a plurality of drying positions is provided.

### EMBODIMENTS

In below, embodiments of the present disclosure will be described with the reference to figures.

### [Abstract]

A substrate processing apparatus of the present embodiment includes processing rooms to perform a plurality of processes, and is a single-wafer type apparatus that performs processing on a plurality of substrates contained and carried in a cassette (FOUP) in the previous process one by one inside each processing room.

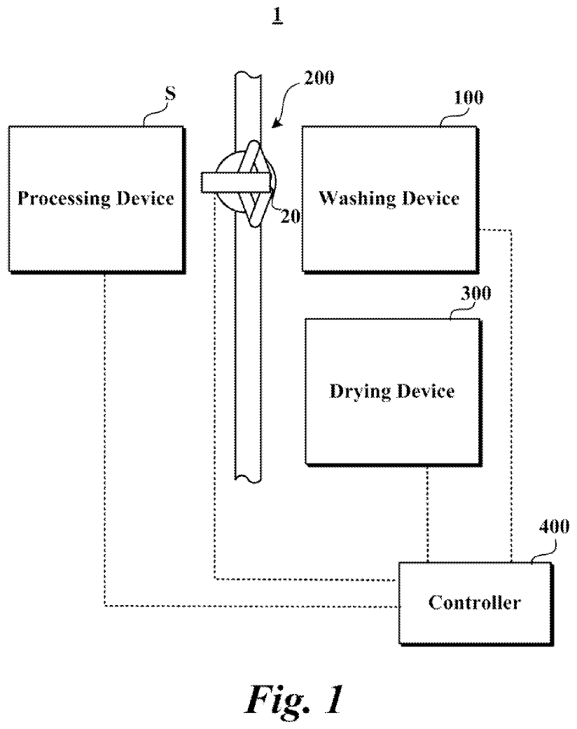

As illustrated in FIG. 1, a substrate processing apparatus 1 includes a processing device S, a washing device 100, a transporter 200, a drier 300, and a controller 400. For example, the processing device S is an etching device which supplies processing liquid on a rotating substrate W to remove unnecessary film and leaves circuit patterns. The washing device 100 washes the substrate W etched by the etching device using washing liquid. The transporter 200 carries the substrate W between the processing rooms. The drier (substrate drying apparatus) 300 heats the substrate W washed using the washing liquid while rotating the substrate W to dry the substrate W. The controller 400 controls the above-described devices.

Note that, for example, the substrate W processed in the present embodiment is semiconductor wafers. The washing liquid that is processing liquid for washing may be alkali washing liquid (APM), DIW (ultrapure water), or IPA (2-propanol:isopropyl alcohol). Surface tension of IPA is smaller lower than ultrapure water, and has high volatility.

[Washing Device]

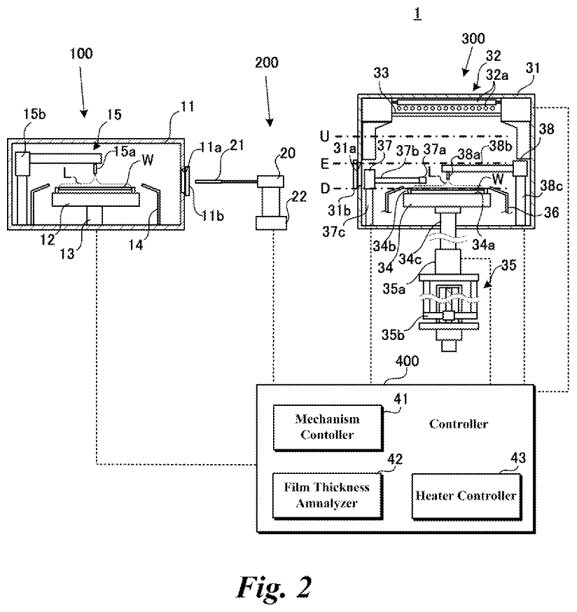

As illustrated in FIG. 2, the washing device 100 includes a washing room 11 that is a container to perform washing therein, a support 12 which supports the substrate W, a rotation mechanism 13 which rotates the support 12, a cup 14 which receives the washing liquid L scattered around the substrate W, and a supplier 15 which supplies the washing liquid L. The supplier 15 includes a moving mechanism 15b which moves nozzles 15a and 15b to which the washing liquid L are dropped.

The washing liquid L is supplied from the nozzle 15a to a surface to be processed of the substrate W that is supported by the support 12 and rotated by the rotation mechanism 13 to perform washing. In the washing, APM washing is performed, and then washing by DIW is performed. Furthermore, IPA is supplied after the washing by DIW. The washing room 11 includes an opening 11a to carry in and out the substrate W, and the opening 11a is configured to be openable and closable by a door 11b.

[Transporter]

The transporter 200 includes a handling device 20. The handling device 20 includes a robot hand 21 which holds the substrate W, and a moving mechanism 22. The robot hand 21 holds the substrate W. The moving mechanism 22 moves the robot hand 21 to carry the substrate W after the etching out of the processing device S and carry the substrate W on which liquid film (liquid film of DIW) is formed into the washing device 100. Furthermore, the moving mechanism 22 moves the robot hand 21 to carry the substrate W after the washing out of the washing device 100 and carry the substrate W on which liquid film (liquid film of DIW or IPA) is formed into the drier 300.

[Drier]

As illustrated in FIG. 1, the drier 300 includes a drying room 31, a heater 32, a window 33, a support 34, a driving mechanism 35, a cup 36, a measuring unit 37, and a supplier 38. The drying room 31 is a container for perform drying the substrate W inside the room. The drying room 31 has a box-shape such as cubes and cuboids. An inner wall of the drying room 31 is coated by silica to improve the dust-resistance. An opening 31a is provided in the drying room 31 for carrying the substrate W in and out. The opening 31a is openable and closable by a door 31b.

The heater 32 is a device to heat the substrate W. The heater 32 is provided in the upper portion inside the drying room 31. The heater 32 includes a lamp 32a such as halogen lamps and infrared lamps. The lamp 32a of the present embodiment is a straight pipe, and two layers of a plurality of the lamps 32a arranged horizontally in parallel with each other are layered so that a first layer and a second layer are arranged to be orthogonal to each other, forming a lattice as a whole. By this, the substrate W can be heated uniformly. Note that the heater 32 facilitates the production of a gas layer due to the heat of the substrate W by using an electromagnetic wave (IR wave) with a wavelength that can heat the substrate W easier than the washing liquid L.

The window 33 is a component through which the electromagnetic wave from the heater 32 can permeate. For example, the window 33 may be a plate made of quartz. The window 33 is provided directly below the heater 32 in the drying room 31 and divides a space between the heater 32 and the support 34 so that metal pollution caused by particles produced when material of a connector of the lamp 32a expands or contracts due to repetition of lighting of the lamp 32a from attaching to the substrate W from above can be prevented.

The support 34 supports the substrate W. The support 34 includes a rotation table 34a, a plurality of holders 34b, and a rotation axis 34c. The rotation table 34a is in a cylindrical shape with diameter larger than the substrate W and a planar circular upper surface. The plurality of the holder 34b is arranged positions along an outer circumference of the substrate W at equal intervals, and holds the substrate W horizontally with a space between an upper surface of the rotation table 34a. The plurality of the holder 34b is arranged to be movable between a closing position in contact with an edge of the substrate W and an opening position distant from an edge of the substrate W by an unillustrated opening and closing mechanism. The rotation axis 34c supports the rotation table 34a from below and is an axis in the vertical direction that is a center of the rotation.

The driving mechanism 35 is a mechanism that can lift the substrate W up and down while rotating the substrate supported by the driving mechanism 34. The driving mechanism 35 includes a rotation unit 35a and a lift 35b. The rotation unit 35a includes a drive source such as motors, and rotates the support 34 via the rotation axis 34c. The lift 35b includes a driving mechanism in which a slider ascends and descends by ball screws rotating by a motor, and moves the support 34 up and down together with the rotation unit 35a.

In the present embodiment, a standby position D and a drying position U are set for the positions of the support 34 that moves by the driving mechanism 35. The standby position D is a position distant from the heater 32 to receive the substrate W on which liquid film by the washing liquid L was formed and which was carried into the drying room 31. In detail, the standby position D is at a position lower than a detector 37a and a nozzle 38a described later. The reason to receive and support the substrate W at the position distant from heater 32 is as follows. That is, even if the lamp 32a is only turned on while performing the drying, the temperature rises to a level at which the washing liquid L evaporates because the quartz window 33 which has bad heat conductivity accumulates heat. In particular, by repeating the drying, the accumulation of heat in the window 33 proceeds. When the substrate W on which liquid film by the washing liquid L was formed is carried into the drying room 31 under this condition, the liquid film on the substrate W starts to evaporate due to radiant heat. However, not all of the liquid film evaporates instantaneously, but only part of the liquid film evaporates, causing ununiformly dried condition. The surface tension of the remaining liquid film causes pattern blockade. Therefore, the substrate W needs to be supported at the position distant from the heater 32 to avoid the effect of the radiant heat. Accordingly, the standby position D is a position that is away enough (position less affected by heat) from the heater 32 so that the processing liquid (processing liquid when the substrate W was carried into the drying room 31) applied on the surface to be processed of the substrate W would not evaporate by the radiant heat accumulated on the window 33 which was repeatedly heated by the heater 32. The drying position U is a position where the substrate W which got close to the heater 32 and which was heated by the heater 32 produces the gas layer between the liquid film and the substrate W. The standby position D of the present embodiment is lower than an upper edge E of the opening 31a, and the drying position U is higher than the upper edge E of the opening 31a.

The cup 36 is formed in a cylindrical shape to surround the support 34 from around (refer FIG. 2). An upper portion of circumferential wall of the cup 36 inclines toward the inner side in the radial direction and is opened so that the substrate W on the support 34 is exposed. The cup 36 receives the washing liquid L scattered from the rotating substrate W and let the washing liquid L flow downward. An ejection opening (not illustrated) to eject the flowing washing liquid L is formed in a bottom surface of the cup 36. Note that the cup 36 is connected to the driving mechanism 35 and is provided ascendable and descendable by with the support 34.

The measuring unit 37 measures the film thickness of the liquid film on the substrate W carried into the drying room 31 and is at the standby position D. The measuring unit includes the detector 37a, swing arm 37b, and swing mechanism 37c. The detector 37a may be laser displacement meters or cameras. The detector 37a is provided at a tip of the swing arm 37a, and the swing arm 37b moves the measuring unit 37a between a measuring position where the measuring unit 37a faces with middle portion between a center of the surface to be processed and an outer circumferential edge of the substrate W on the support 34, and the standby position D that is distant from the measuring position and enables the substrate W to be carried in and out. The swing mechanism 37c is a mechanism to swing the swing arm 37b.

For example, optical interference principle may be used as a film thickness measuring method by the measuring unit 37. Note that, as another example, weight scale inside the support 34 may be used. When using the weight scale, weight of the liquid film of the substrate W (weight of liquid film=weight of substrate including liquid film−weight of substrate) is theoretically or experimentally converted into the thickness of the liquid film.

The supplier 38 supplies the washing liquid L on the substrate W which has been carried into the drying room 31 and is at the standby position D. The suppler 38 include the nozzle 38a, a swing arm 38b, and a swing mechanism 38c. The nozzle 38a supplies the washing liquid L to the middle portion of the surface to be processed of the substrate W. The washing liquid L is supplied to the nozzle 38a via piping, etc. (not illustrated), from a storage (not illustrated) outside the drying room 31.

Types of the washing liquid L supplied by the supplier 38 is determined according to types of liquid that would be filled on the substrate W in the end in a rinsing process after alkali washing in the washing process by the washing device 100. That is, when the rinsing process ends with DIW, the substrate W is filled with DIW and is carried from the washing device 100 to the drying apparatus 300. In the case of DIW, the supplier 38 supplies DIW. When DIW is replaced with IPA in the end, the substrate W is filled with IPA and is carried from the washing device 100 to the drying apparatus 300. In the case of IPA, the supplier 38 newly supplies IPA because IPA may volatilize while being carried or may absorb moisture in the air while being carried.

The nozzle 38a is provided at a tip of the swing arm 38b, and the swing arm 38b moves the nozzle 38 between a supplying position where the nozzle 38a faces with the middle portion of the surface to be processed of the substrate W on the support 34, and an evacuation position that enables the nozzle 38a to move from the supplying position and the loading the substrate W in and out. The swing mechanism 38c is a mechanism to swing the swing arm 38b. Note that the drying position U is higher than the supplier 38 that is at the supplying position to supply the washing liquid L on the substrate W.

[Controller]

The controller 400 is a computer to control each portion of the substrate processing apparatus 1. The controller 400 includes a processor which executes programs, a memory which stores various information such as programs and operation condition, and a driving circuit which drives each component. That is, the controller 400 controls the processing device S, the washing device 100, the transporter 200, and the drier 300. Note that the controller 400 includes an inputter which inputs information and a display which displays information.

The controller 400 includes a mechanism controller 41, a film thickness analyzer 42, and a heater controller 43. The mechanism controller 41 controls mechanism in each portion. For example, the mechanism controller 41 controls the rotation speed, and the timings to start and stop rotation of the support 34 by controlling the rotation unit 35a of the driving mechanism 35. Furthermore, the mechanism controller 41 controls the distance (gap) between the support 34 and the heater 32 by controlling the lift 35b of the driving mechanism 35. In detail, the controller 400 make the support 34 to hold the substrate W at the standby position D, and then adjust the film thickness of the liquid film of the washing liquid L supplied to the surface to be processed of the substrate W, rotates and lift up the substrate W to the drying position U, and turns on the lamp 32a to dry the substrate W for predetermined period of time. Then, the substrate W is descended to the standby position D while keeping the rotation. In addition, the controller 400 controls the swinging of the nozzle 38a, the ejection of the washing liquid L, the swinging of the detector 37a, and the measurement by the detector 37a.

The film thickness analyzer 42 analyzes the thickness of the washing liquid L measured by the measuring unit 37. The film thickness analyzer 42 determines whether the thickness of the washing liquid L measured by the measuring unit 37 is in the predetermined threshold range or not. Then, if the thickness (film thickness value) of the washing liquid L measured by the measuring unit 37 is determined to be in the predetermined threshold range, the film thickness analyzer 42 transmits a permission signal to the mechanism controller 41 to allow the driving mechanism 35 to rotate and lift up the substrate W for the thickness of the liquid film being appropriate. When the mechanism controller 41 receives the permission signal, the mechanism controller 41 transmits a signal to the mechanism controller 41 to instruct the support 34 to rotate and lift up the substrate W. Note that, for example, the appropriate film thickness is 10 μm or less for DIW and 100 μm or less for IPA. This thickness is thickness enough for the liquid film to not evaporate from the substrate W when getting close to the heater 32 (when getting close to the window 33) and to be excellently dried when the drying process by Leidenfrost phenomenon is performed. However, these values are only examples, and in practice, appropriate film thickness may be acquired beforehand by experiment, etc. Furthermore, for example, the rotation speed of the substrate W is about 200 to 300 rpm, and in this range, the thickness of the liquid film can be maintained at the predetermined thickness even when the thickness of the liquid film is adjusted.

(Heating Control Performed when Support Stops at Drying Position)

The heater controller 43 controls the heater 32 according to the instruction from the mechanism controller 41. When the support 34 comes to and stops at the drying position U, the heater controller 43 receives the instruction signal output from the mechanism controller 41 and controls the heater 32 to perform heating on the surface to be processed of the substrate W on the support 34. The heating by the heater 32 is controlled to rapidly heat the surface to be processed of the substrate W to be equal to or more than Leidenfrost temperature (temperature at which Leidenfrost phenomenon occurs) by making the lamp 32a to emit light for few seconds, so as to make the washing liquid L on the surface to be processed of the substrate W to be a liquid ball.

When the film thickness analyzer 42 determines that the measured thickness of liquid film of the washing liquid L is less than the lower limit of the predetermined threshold range, the mechanism controller 41 output an instruction to the supplier 38 to supply the processing liquid (washing liquid L) for the liquid film being too thin. By this, the predetermined amount (for predetermined period of time) of the washing liquid L is supplied on the surface to be processed of the substrate W from the nozzle 38a, and the thickness of the liquid film will be in the predetermined threshold range. Then, as described above, the drying by the rotation and lifting up of the substrate W is performed. The substrate W may be stopped from rotating when supplying the washing liquid L, or may kept to rotating.

When the film thickness analyzer 42 determines that the measured thickness of liquid film of the washing liquid L is more than the upper limit of the predetermined threshold range, the mechanism controller 41 output an instruction to the driving mechanism 35 to rotate the support 34 for the liquid film being too thick. By this, the washing liquid L on the substrate W is scattered by centrifugal force along with the rotation of the support 34, and the thickness of the liquid film will be in the predetermined threshold range. Then, as described above, the drying by the rotation and lifting up of the substrate W is performed.

[Operation]

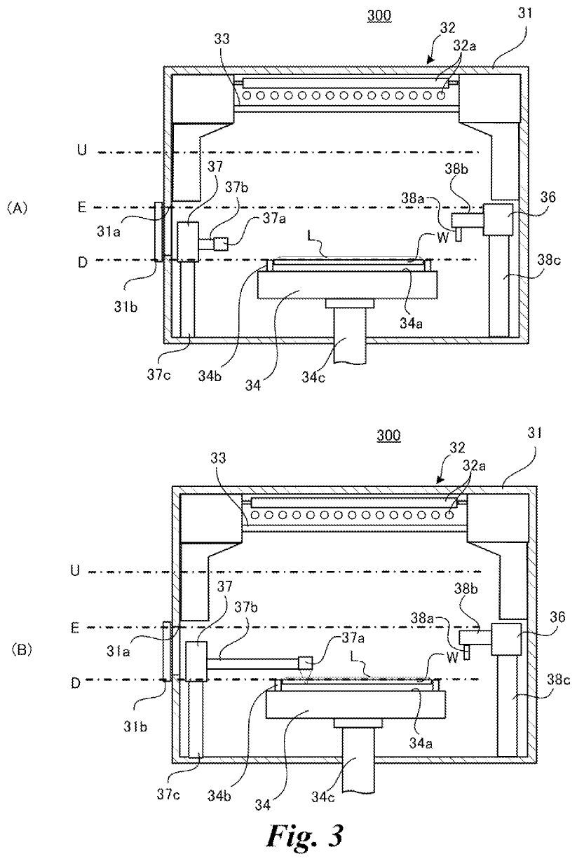

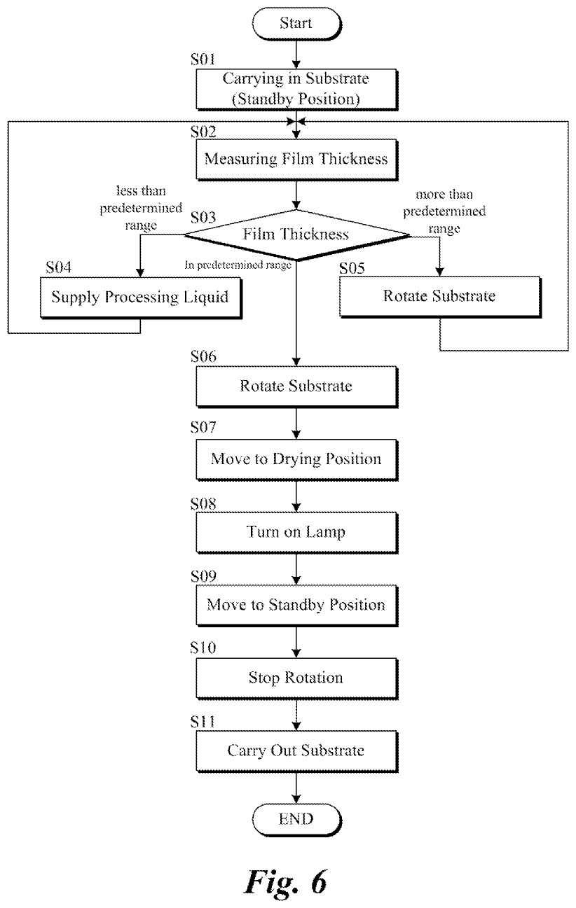

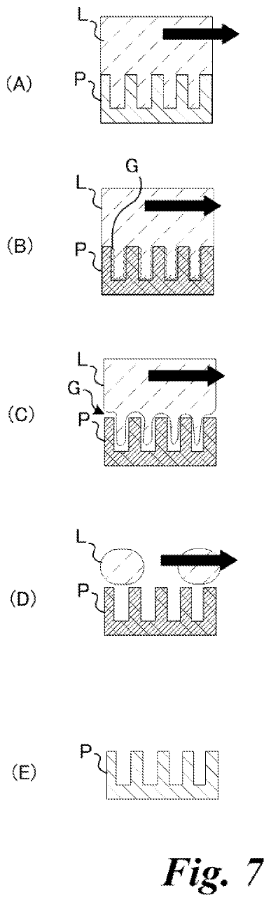

Operation of the substrate processing apparatus 1 of the present embodiment as described above will be explained by referring to the explanation diagram of FIGS. 3 to 5, the flowchart of FIG. 6, and the operation explanation diagram of FIG. 7, in addition to the above FIGS. 1 and 2. Note that the substrate processing method to process the substrate W by the following procedures is also an aspect of the present embodiment.

As illustrated in FIG. 1, the substrate W which has been etched in the processing device S is carried into the washing device 100 by the transporter 200. In the washing device 100, the supplier 15 supplies APM on the surface to be processed of the substrate W to wash the substrate W by alkali while the support 12 holding the substrate W rotates, and then, the supplier 15 supplies DIW on the surface to be processed to wash the substrate W by pure water. Furthermore, after the washing by pure water, the supplier supplies IPA on the surface to be processed of the substrate W. By this, DIW supplied on the on the surface to be processed of the substrate W is replaced with IPA. The transporter 200 carries the washed substrate W out of the washing device 100 and carries the washed substrate W into the drying apparatus 300. Note that, after the washing by pure water, DIW supplied on the on the surface to be processed of the substrate W may not be necessarily replaced with IPA. That is, the washing process may be completed only by the washing by pure water by DIW.

As illustrated in FIG. 3(A), the holding component 34b of the support 34 at the standby position D holds the substrate W which the liquid film (DIW or IPA) is formed on the surface to be processes and which has been carried into the drying room 31 of drying apparatus 300 from the opening 31a (step S01). As illustrated in FIG. 3 (B), the detector 37a of the measuring unit 37 measures the film thickness of the liquid film on the substrate W (step S02).

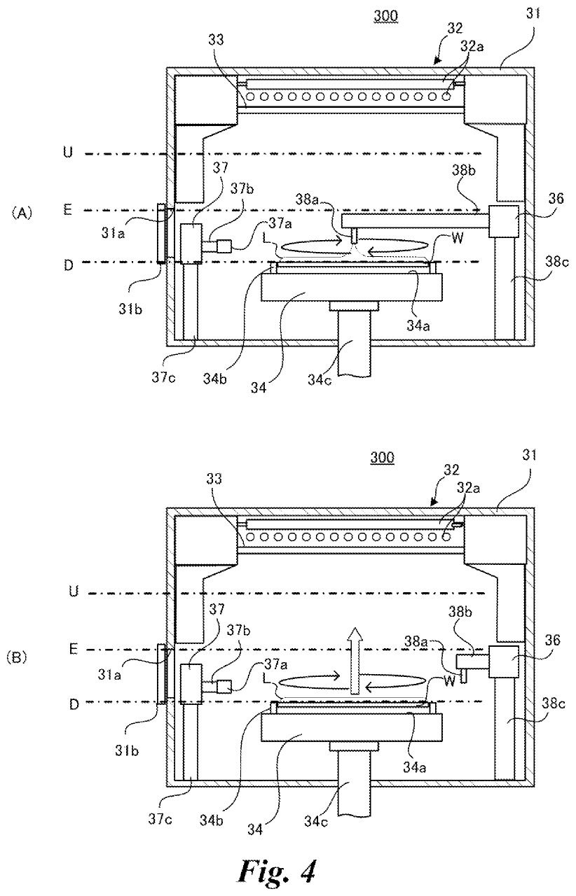

As illustrated in FIG. 4(A), when the film thickness is thin (less than predetermined range in step S03), the supplier 38 further supplies the washing liquid L on the liquid film of the substrate W to adjust the film thickness (step S04). When the film thickness is thick (more than predetermined range in step S03), the support 34 rotates and scatters the washing liquid L from the rotating substrate W to adjust the film thickness (step S05).

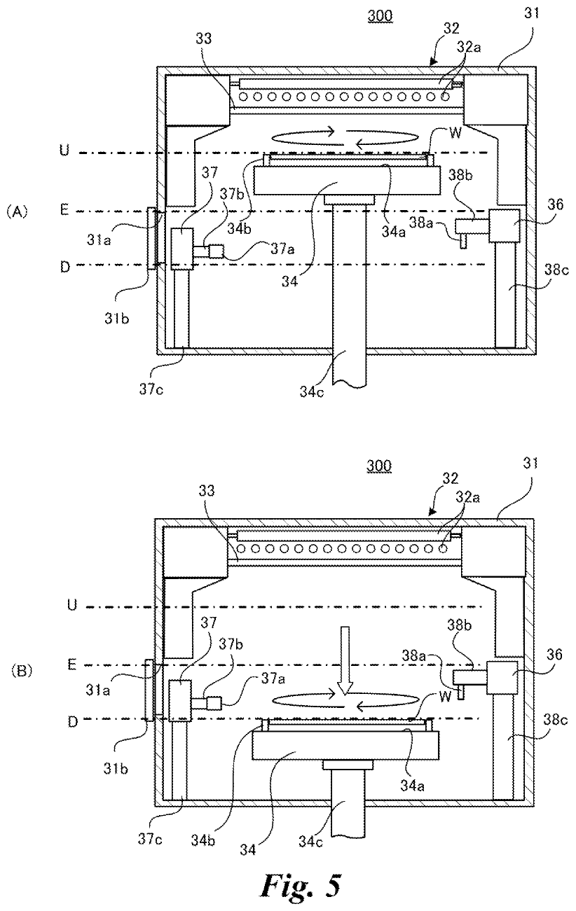

When the film thickness is appropriate (equal to predetermined range in step S03) or when the film thickness became appropriate after adjustment, the support 34 rotates the substrate W as illustrated in FIG. 4(B) (step S06), and the support 34 lifts up to the drying position U to move the substrate W close to the heater 32 as illustrated in FIG. 5(A) (step S07). By rotating the substrate W before being heated by the heater 32, the liquid film of the washing liquid L on the surface to be processed of the substrate W rotates together with the substrate W, so that the liquid film of the washing liquid L continues to rotate by inertial force even after the gas layer is produced between the surface to be processed of the substrate W and the liquid film, thereby producing centrifugal force.

By making the lamp 32a of the heater 32 to light for a predetermined period of time (from few seconds to dozens of seconds), the substrate W is rapidly heated to the temperature (equal to or more than the boiling point of the washing liquid L) at which Leidenfrost phenomenon occurs, so that the liquid film of the washing liquid L floats and becomes liquid ball due to the gas layer produced at the boundary of the liquid film of the washing liquid L on the surface to be processed of the substrate W and the surface to be processed of the substrate W, and the washing liquid L is scattered by centrifugal force so that the substrate W is dried (step S08). That is, in the washing liquid L contacting the pattern P on the surface to be processed of the substrate W as illustrated in FIG. 7(A), since only the substrate W is instantaneously heated by the lighting of the lamp 32a, the portion of the washing liquid L contacting the surface to be processed of the substrate W starts to be gasified faster than the other portion of the washing liquid L, a layer of gas which is the gasified liquid (washing liquid), that is, the gas layer G is formed around the pattern P.

Therefore, the liquid (washing liquid L) between the adjacent patterns P instantaneously float from between the pattern P by the gas layer G as illustrated in FIG. 7(C), and turns into liquid balls at once (Leidenfrost phenomenon) as illustrated in FIG. 7(D). In figures, as indicated by black arrows, centrifugal force by rotation is applied to the washing liquid L, and since the produced liquid balls are scattered from the substrate W by centrifugal force, the surface to be processed of the substrate W is dried as illustrated in FIG. 7(E).

In this way, by making the washing liquid L present between the pattern P to float from between the pattern P at the entire surface to be processed on the substrate W, the drying speed of the liquid on the surface to be processed of the substrate W becomes uniform, and the pattern P is prevented from collapsing by the collapsing force (for example, surface tension) due to the remaining liquid. Furthermore, the thickness of the liquid film of the washing liquid L on surface to be processed of the substrate W is adjusted to be appropriate. When the liquid film is thicker than the appropriate thickness, stripe watermarks is produced on the surface to be processed of the substrate W when the substrate W is dried, and the drying defect occurs. When rapidly heating the substrate W to make the processing liquid on the substrate W into liquid balls, the number of the liquid balls increases as the film thickness of the processing liquid gets thicker. If the number of the liquid balls increases, the liquid balls in contact with the surface to be processed of the substrate W until the liquid balls are ejected outside the surface to be processed by centrifugal force produced by the rotating substrate W increases. Since the surface to be processed of the substrate W is cooled when contacting the liquid balls due to heat of vaporization, if there are too many liquid balls, portions where the temperature is less than the temperature that causes Leidenfrost phenomenon, that is, portions that are dried by normal drying and not by rapid drying may occur on part of the surface to be processed of the substrate W even at the time of rapid heating. For example, in this case, traces of liquid balls being ejected outside the surface to be processed remains, and liquid stains such as stripe watermarks may be produced. Furthermore, since there are more numbers of the liquid balls, a part of the liquid balls of the washing liquid L would not be ejected from the substrate W and remains between the pattern P in part of the surface to be processed of the substrate W, causing the collapsing of the pattern P in said part. Therefore, since the thickness of the liquid film is adjusted to the appropriate thickness that does not produce liquid stain before heating, the number of the liquid balls in the surface to be processed of the substrate W can be adjusted, and the drying defect can be prevented.

Then, as illustrated in FIG. 5(B), the support 34 descend to the standby position D while keeping the rotation of the substrate W (step S09). After the support 34 stops the rotation of the substrate W (step S10), the transporter 200 carries the substrate W out of the drying room 31 from the opening 31a (step 11).

[Effect]

(1) The drier (substrate drying apparatus) 300 of the present embodiment as described above, includes the heater 32 which heats the substrate W, the drying room 31 into which the substrate W in which the liquid film of the processing liquid is formed on the surface to be processed is carried in, the support 34 which receives the substrate W carried into the drying room 31 at the standby position D distant from the heater 32, and the driving mechanism 35 which moves the substrate W close to the heater 32 and ejects the liquid at which the gas layer is produced between the substrate W heated by the heater 32 and the liquid film by centrifugal force due to the rotation of the substrate W.

The substrate processing apparatus 1 of the present embodiment includes the processing device S which supplies the processing liquid while rotating the substrate W, the washing device 100 which supplies the processing liquid while rotating the processed substrate W and washes the substrate W, and the transporter 200 which carries the substrate W which was washed in the washing device 100 and has the liquid film of the processing liquid formed on the surface out of the washing device 100 and carries the substrate W into the drying apparatus 300.

By this, since the substrate W is hold at the standby position D distant from the heater 32 when being carried into the drying room 31, the heating by the radiant heat from around the heater 32 would not occur, and the drying can be suppressed. That is, when the substrate W on which the liquid is supplied is carried into the drying room 31, the substrate is received and held by the support 34 that is positioned at the standby position D way from the heater 32, so that the radiant heat (heat accumulation) from the window 33, etc., heated by the heater 32 would not dry the washing liquid L supplied in the surface to be processed of the substrate W ununiformly, and watermarks and collapsing of pattern due to the drying can be suppressed.

This radiant heat (heat accumulated in the window) is a temperature enough to dry the processing liquid on the substrate W (more than the boiling point of the processing liquid). That is, the window 33 which is repeatedly heater by the heater 32 has the temperature higher than the substrate W heated by the heater 32. Since the standby position D is a position that is distant from the window 343 as describe above, normal drying (drying by heat) that is the liquid film on the substrate W dried by the radiant heat right after being carried into the drying room 31 can be prevented. Furthermore, the collapsing the pattern when the drying start on a part of the surface to be processed of the substrate W that is not the uniform drying of the entire substrate can be prevented. That is, the collapsing of the pattern before adjusting the liquid film by the supplier 38 causing the product defect right before performing the drying by the heater 32 can be prevented.

Furthermore, at the time of drying, by moving the substrate W to the drying position U and perform heating by the heater 32 while rotating the substrate W, the liquid balls floated by the gas layer can be ejected and instantaneously dried. Therefore, the blockade of the pattern by the ununiform drying can be reduced. Furthermore, since the substrate W is moved nearer to the heater 32, the output of the heater 32 can be suppressed.

(2) The opening 31a to carry the substrate W in and out is provide in the drying room 31, and the standby position D is lower than the upper edge E of the opening 31a and the drying position U is higher than the upper edge E of the opening 31a. Therefore, the distance from the substrate W to the heater 32 can be longer, and the effect due to the radiant heat can be suppressed.

(3) The measuring unit 37 measures the thickness of the liquid film on the substrate W which had been carried into the drying room 31 and is at the standby position D, the supplier 38 supplies the processing liquid on the liquid film on the substrate W which had been carried into the drying room 31 and is at the standby position D, and the controller 400 adjusts the thickness of the liquid film on the substrate W at the standby position D by controlling and the driving mechanism 35 and the supplier 38 according to the measurement result by the measuring unit 37.

By this, the film thickness can be adjusted to appropriate thickness at the standby position D that can suppress the drying by the effect of the radiant heat before drying the substrate W. If the liquid film is thin, a part of the pattern P collapse before performing the heating because the liquid film on the surface to be processed dries ununiformly by the radiant heat of the window 33 when lifting up the substrate W from the standby position D to the drying position U. That is, the normal drying in which the liquid film evaporates and dries by the radiant heat occurs. Furthermore, If the liquid film is thick, the liquid balls increase as described above, and the liquid balls in contact with the surface to be processed of the substrate W until the liquid balls are ejected outside the surface to be processed by centrifugal force produced by the rotating substrate W increases. Since the surface to be processed of the substrate W is cooled when contacting the liquid balls due to heat of vaporization, if there are too many liquid balls, portions where the temperature is less than the temperature that causes Leidenfrost phenomenon, that is, portions that are dried by normal drying and not by rapid drying may occur on part of the surface to be processed of the substrate W even at the time of rapid heating. In the present embodiment, since the film thickness is appropriately adjusted before drying the substrate W, the drying by the normal drying can be prevented.

(4) The drying position U is higher than the supplier 38 at the supplying position to supply the processing liquid on the substrate W. Therefore, by lifting up the substrate W to the drying position U higher than the supplying position while rotating the substrate W, centrifugal force can be applied to the liquid film beforehand, and the liquid balls produce by Leidenfrost phenomenon can be ejected by centrifugal force. Meanwhile, even if the substrate W is lifted up to the drying position U without the rotation, centrifugal force would not be applied to the liquid film itself. When the liquid film floats from the pattern P by Leidenfrost phenomenon due to the heating by the heater 32, centrifugal force would not be applied to the already floated liquid film even when the rotation of the substrate W starts. That is, at the interface of the liquid ball and the surface to be processed of the substrate W (the washing liquid L around the liquid ball is gasified and is forming the gas layer), the liquid ball is floating, and the rotation force of the substrate W would not be applied to the liquid ball. Accordingly, the liquid ball cannot be ejected from the surface to be processed of the substrate W. In the present embodiment, since the substrate W is lifted up to the drying position U higher than the supplying position while rotating the substrate W, centrifugal force can be applied to the liquid balls so that the liquid balls can be ejected.

(5) The driving mechanism 35 moves the substrate W to the standby position D while rotating the substrate W supported by the support 34 after drying the substrate W at the drying position U. Therefore, liquid (mist atmosphere) fluttering around the substrate W right after being ejected is prevented from attaching to the substrate W again.

### Modified Example

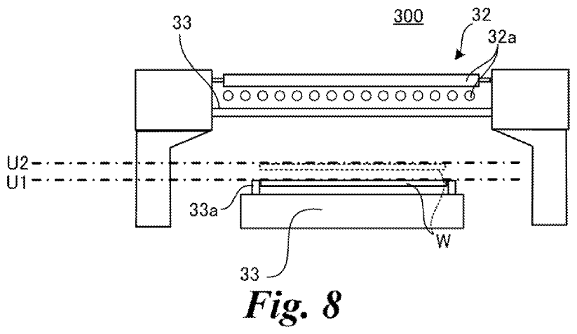

(1) As illustrated in FIG. 8, a plurality of the drying positions U1 and U2 may be set at positions that each have different distance from the heater 32 in accordance with the type of the processing liquid. For example, when the processing liquid includes IPA, since the volatility of IPA is high, the drying position is set to be the drying position U1 that is more distant from the heater 32. When the processing liquid is only pure water, since the pure water is hard to evaporate, the drying position is set to be the drying position U2 that is less distant from the heater 32. For example, the difference between the distance is about 10 mm. Note that the drying position U1 and U2 can be acquired by experiment, etc., beforehand to set the appropriate position.

(2) Coating to suppress the transformation of the material may be applied to the inner wall of the drying room 31. Drops of the processing liquid scatters and moisture caused by the heating diffuses entirely inside the drying room 31. Therefore, for example, when aluminum with high reflectivity is used as the material of the drying room 31, since the aluminum is in the high temperature and under vapor atmosphere, aluminum is oxidized to aluminum oxide and whitens. Therefore, by applying silica coating that has silicon dioxide as the main component on the inner wall of the drying room 31, the transformation of the material can be prevented. By this, the production of particles and metal pollution can be prevented.

(3) A cooling device to cool the window 33 may be provided to suppress the effect by the radiant heat. For example, quartz window 33 may be double-layered, and cooling gas may be flown in between. However, even in this case, the standby position D distant from the heater 32 must be set because there is a limit for the cooling device to cool the window.

(4) In the processing by the processing device S, operation and processing liquid in the processing is not limited to the above examples as long as the process need washing and drying in the end. The substrate W to be processed and the processing liquid is also not limited to the above examples.

### Other Embodiment

In above, although the embodiment of the present disclosure and modified examples thereof are described, they are only provided as examples and are not intended to limit the scope of invention. These new embodiments described above may be implemented in other various forms, and various omission, replacement, and modification may be performed without departing from the abstract of the claim. The embodiments and modifications thereof are included in the scope and abstract of the invention and invention described in scope of claims.

### REFERENCE SIGN

1: substrate processing apparatus
11: washing room
11a: opening
11b: door
12: support
13: rotation mechanism
14: cup
15: supplier
15a: nozzle
15b: moving mechanism
20: handling device
21: robot hand
22: moving mechanism
31: drying room
31a: opening
31b: door
32: heater
33: window
34: support
34a: rotation table
34b: holder
34c: rotation axis
35: driving mechanism
35a: rotation unit
35b: lift
36: cup
37: measuring unit
37a: detector
37b: swing arm
37c: swing mechanism
38: supplier
38a: nozzle
38b: swing arm
38c: swing mechanism
41: mechanism controller
42: film thickness analyzer
43: heater controller
100: washing device
200: transporter
300: drier
400: controller

1. A substrate drying apparatus comprising:
a heater that heats a substrate;
a drying room inside which the heater is housed and into which the substrate is carried, wherein liquid film of processing liquid is formed on a surface of the substrate;
a support which receives the substrate that has been carried into the drying room at a standby position distant from the heater; and
a driving mechanism which rotates the substrates supported by the support while moving the substrate to a drying position near the heater to eject the liquid film by centrifugal force caused by rotation of the substrate, wherein a gas layer is produced between the liquid film and the substrate heated by the heater.

2. The substrate drying apparatus according to claim 1, wherein:
an opening to carry the substrate in and out is provided in the drying room,
the standby position is lower than an upper edge of the opening, and
the drying position is higher than an upper edge of the opening.

3. The substrate drying apparatus according to claim 1, comprising:
a measuring unit which measures film thickness of the liquid film on the surface of the substrate which has been carried into the drying room and is supported by the support at the standby position,
a supplier which supplies the processing liquid on the liquid film on the surface of the substrate which has been carried into the drying room and is supported by the support at the standby position, and
a controller which adjusts the film thickness of the liquid film on the surface of the substrate at the standby position by controlling and the driving mechanism and the supplier according to measurement result by the measuring unit.

4. The substrate drying apparatus according to claim 3, wherein the drying position is higher than the supplier at a supplying position to supply the processing liquid to the substrate.

5. The substrate drying apparatus according to claim 1, wherein a plurality of the drying position is set at positions with different distance from the heater according to types of the processing liquid.

6. The substrate drying apparatus according to claim 1, wherein the driving mechanism moves the substrate to the standby position while rotating the substrate supported by the support after drying the substrate at the drying position.

7. A substrate processing apparatus comprising:
a processing device which applies the processing liquid to the substrate and processes the substrate, while rotating the substrate;
a washing device which applies washing liquid to the processed substrate and washes the processed substrate, while rotating the processed substrate;
a substrate drying apparatus according to claim 1; and
a transporter which carries out the substrate washed by the washing device, wherein liquid film of the washing liquid is formed on the surface of the substrate, and carries the substrate into the substrate drying apparatus.
